(19) United States
(12) Patent Application Publication
(10) Pub. No.: US 2006/0079087 A1
(43) Pub. Date: Apr. 13, 2006

(54) Method of producing semiconductor device

(75) Inventors: Kazuo Kawamura, Kawasaki (JP); Satoshi Inagaki, Kawasaki (JP); Takashi Saiki, Kawasaki (JP); Ryou Nakamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/041,217

(22) Filed: Jan. 25, 2005

(30) Foreign Application Priority Data
Oct. 13, 2004 (JP) 2004-299280

(51) Int. Cl. H01L 21/44; H01L 21/4763; H01L 21/336

(52) U.S. Cl. 438/664; 438/663; 438/655; 438/305; 438/592

(57) ABSTRACT

A method of producing a semiconductor device is disclosed that is able to reduce fluctuations of a sheet resistance of a silicide layer in the semiconductor device formed by a salicide process. When depositing a titanium nitride film on a cobalt film in the salicide process, the thickness of the titanium nitride film is set to be sufficiently small so that a nano-grain structure or an amorphous structure is formed in the titanium nitride film. In the titanium nitride film, the titanium composition is enriched.

### CROSS-REFERENCE TO RELATED APPLICATION

This patent application is based on Japanese Priority Patent Application No. 2004-299280 filed on Oct. 13, 2004, the entire contents of which are hereby incorporated by reference.

### BACKGROUND OF THE INVENTION

1. Field of the Invention

The present invention generally relates to a method of producing a semiconductor device, and particularly, to a method of producing a miniaturized semiconductor device having a silicide layer of low resistance.

2. Description of the Related Art

In a semiconductor device of the related art, thin silicide layers each having a low resistance are formed on the surfaces of a source region, a drain region, and a gate electrode, respectively, so as to reduce the resistance between the source and the drain, and the resistance of the gate. Generally, such a silicide layer is fabricated through the following steps: first, depositing metal films, such as cobalt, on silicon surfaces constituting the surfaces of the source region, the drain region, and the gate electrode, and processing the metal films by thermal treatment so that reactions occur between the metal films and the silicon surfaces to produce silicide layers, and further, removing the un-reacted portions of the metal films by wet etching, obtaining the silicide layers. This is the so-called “Salicide (Self-alignment silicide) process”.

FIG. 1 is a cross-sectional view of a semiconductor device 10 having a silicide layer in the related art.

As illustrated in FIG. 1, the semiconductor device 10 is formed in an element region 11A in a silicon substrate 11, which has a p-type or n-type well 11W and is defined by STI (shallow trench isolation) element separation regions 11B. The semiconductor device 10 includes a poly-silicon gate electrode 13 formed on the silicon substrate 11 with a gate insulating film 12 in between, a source extension region 11a and a drain extension region 11b in the silicon substrate 11 at two sides of the poly-silicon gate electrode 13, and a source region 11c and a drain region 11d in the silicon substrate 11 on outer sides of sidewall insulating films 13A and 13B of the poly-silicon gate electrode 13, respectively, partially overlapping the respective source extension region 11a and the drain extension region 11b. Silicide layers 11e, 11f, and 13a are formed on the surfaces of the source region 11c, the drain region 11d, and the poly-silicon gate electrode 13, respectively, by the Salicide process.

In the related art, titanium silicide is used for the silicide layer. In recent miniaturized semiconductor devices, however, since the sheet resistance of titanium silicide fluctuates remarkably, cobalt silicide, especially, cobalt disilicide, which has a low resistance, is used instead of titanium silicide.

FIGS. 2A through 2C are cross-sectional views illustrating a method of fabricating the semiconductor device in FIG. 1 by the salicide process.

Continuing from. FIG. 2C, FIGS. 3A through 3C are cross-sectional views illustrating the method of fabricating the semiconductor device in FIG. 1 by the salicide process.

In the step illustrated in FIG. 2A, on the silicon substrate 11, the poly-silicon gate electrode 13 and the diffusion regions 11a through 11d are formed in the element region 11A defined by the element separation regions 11B.

In the step illustrated in FIG. 2B, on the structure in FIG. 2A, a cobalt film 14 is deposited, for example, by sputtering, so as to cover the source diffusion region 11c and the drain diffusion region 11d, and the poly-silicon gate electrode 13.

In the step illustrated in FIG. 2C, a TiN protection film 15 is deposited, for example, by sputtering, so as to cover the cobalt film 14.

In the step illustrated in FIG. 3A, the structure in FIG. 2C is processed by thermal treatment so that the cobalt film 14 reacts with the surfaces of the source diffusion region 11c, the drain diffusion region 11d, and the poly-silicon gate electrode 13 to form silicide layers 111e, 111f, and 113a, which are primarily formed from CoSi.

Since the thus fabricated CoSi films 111e, 111f, and 113a have high resistances, RTA (Rapid Thermal Annealing) is performed at a temperature, for example, higher than 700° C., to convert CoSi to CoSi₂, thereby obtaining the aforesaid silicide layers 11e, 11f, and 13a.

That is, after the step in FIG. 3A, in the step illustrated in FIG. 3B, the TiN protection film 15 and the un-reacted portion of the cobalt film 14 are removed by wet etching.

In the step illustrated in FIG. 3C, thermal treatment is performed at a high temperature to convert CoSi layers 11e, 111f, and 113a to the CoSi₂ layers 11e, 11f, and 13a, respectively.

Listed below are references which disclose techniques related to the present invention:

Japanese Laid-Open Patent Application No. 10-98012,

Japanese Laid-Open Patent Application No. 2000-284284,

Japanese Laid-Open Patent Application No. 10-195642,

T. Q. Li, et al., J. Vac. Sci. Technolo. A20(3), May/June 2002, pp. 583-588,

J. H. Kang et al., J. Appl. Phys. 86, pp. 346, 1999,

P. Patsalas, et al., Surf. Coat. Technol. 125, pp. 335, 2000,

J. Geng, et al., J. Appl. Phys. 86, pp. 3460, 1999, and

N. Schell, et al., J. Appl. Phys. 91, pp. 2037, 2002.

These references are referred to as reference 1 through 8, below.

### SUMMARY OF THE INVENTION

It is a general object of the present invention to solve one or more of the problems of the related art.

It is a more specific object of the present invention to provide a method of producing a semiconductor device able to reduce fluctuations of sheet resistance of a silicide layer in the semiconductor device formed by a salicide process.

According to a first aspect of the present invention, there is provided a method of producing a semiconductor device having a gate width less than 50 nm, comprising a step of forming a poly-silicon gate electrode pattern having a gate width less than 50 nm on a semiconductor substrate; a step of forming a first diffusion region and a second diffusion region on two respective sides of the poly-silicon gate electrode pattern in the semiconductor substrate; a step of depositing a cobalt film on the semiconductor substrate so as to cover the first diffusion region, the second diffusion region, and the poly-silicon gate electrode pattern; a step of depositing a titanium nitride film on the cobalt film; and a step of, after the step of depositing the titanium nitride film, inducing a reaction between the cobalt film and surfaces of the first diffusion region, the second diffusion region, and the poly-silicon gate electrode pattern so as to form a CoSi₂ film, wherein the titanium nitride film is formed such that a crystal grain diameter of the titanium nitride film is less than a thickness of the titanium nitride film.

According to a second aspect of the present invention, there is provided a method of producing a semiconductor device having a gate width less than 50 nm, comprising: a step of forming a poly-silicon gate electrode pattern having a gate width less than 50 nm on a semiconductor substrate; a step of forming a first diffusion region and a second diffusion region on two respective sides of the poly-silicon gate electrode pattern in the semiconductor substrate; a step of depositing a cobalt film on the semiconductor substrate so as to cover the first diffusion region, the second diffusion region, and the poly-silicon gate electrode pattern; a step of depositing a titanium nitride film on the cobalt film; and a step of, after the step of depositing the titanium nitride film, inducing a reaction between the cobalt film and surfaces of the first diffusion region, the second diffusion region, and the poly-silicon gate electrode pattern so as to form a CoSi₂ film, wherein the titanium nitride film is formed to have an amorphous phase.

According to a third aspect of the present invention, there is provided a method of producing a semiconductor device having a gate width less than 50 nm, comprising: a step of forming a poly-silicon gate electrode pattern having a gate width less than 50 nm on a semiconductor substrate; a step of forming a first diffusion region and a second diffusion region on two respective sides of the poly-silicon gate electrode pattern in the semiconductor substrate; a step of depositing a cobalt film on the semiconductor substrate so as to cover the first diffusion region, the second diffusion region, and the poly-silicon gate electrode pattern; a step of depositing a titanium nitride film on the cobalt film, a composition of said titanium nitride film being denoted as TiₓN_{y} (x+y=1); and a step of, after the step of depositing the titanium nitride film, inducing a reaction between the cobalt film and surfaces of the first diffusion region, the second diffusion region, and the poly-silicon gate electrode pattern so as to form a CoSi₂ film, wherein the composition of the titanium nitride film satisfies x>y.

According to a fourth aspect of the present invention, there is provided a semiconductor device comprising a semiconductor substrate; a poly-silicon gate electrode pattern having a gate width less than 50 nm formed on the semiconductor substrate with a gate insulating film in between; and a first diffusion region and a second diffusion region in the semiconductor substrate on two respective sides of the poly-silicon gate electrode pattern and on respective outer sides of sidewall insulating films of the poly-silicon gate electrode, wherein a CoSi₂ film is formed on surfaces of the first diffusion region, the second diffusion region, and the poly-silicon gate electrode pattern, and an atomic percentage of titanium in the CoSi₂ film is in a range from 0.1% to 1%.

Effects of the present invention are described below.

According to the present invention, the method of producing a semiconductor device having a gate width less than 50 nm includes steps of forming a poly-silicon gate electrode pattern having a gate width less than 50 nm on a semiconductor substrate; forming a first diffusion region and a second diffusion region on two respective sides of the poly-silicon gate electrode pattern in the semiconductor substrate, depositing a cobalt film on the semiconductor substrate so as to cover the first diffusion region, the second diffusion region, and the poly-silicon gate electrode pattern, depositing a titanium nitride film on the cobalt film, and inducing a reaction between the cobalt film and surfaces of the first diffusion region, the second diffusion region, and the poly-silicon gate electrode pattern after the step of depositing the titanium nitride film so as to form a CoSi₂ film. In the above process, the titanium nitride film is formed such that the crystal grain diameter of the titanium nitride film is less than the thickness of the titanium nitride film. Due to this, it is possible to prevent formation of a columnar structure in the titanium nitride film, and prevent diffusion of oxygen atoms through the titanium nitride film. As a result, it is possible to prevent diffusion of the oxygen atoms into the cobalt film, and prevent formation of a non-uniform silicide caused by presence of oxides.

In addition, a very thin titanium nitride film as described above usually has an amorphous phase or a nano-grain structure. Such a titanium nitride film having the amorphous phase or the nano-grain structure is more or less unstable compared with a titanium nitride crystal, and it is thought that the titanium atoms in the titanium nitride film may probably diffuse into the underlying cobalt film. Further, when using such a very thin titanium nitride protection film, it is probable that a tiny amount of oxygen atoms may diffuse into the cobalt film through the titanium nitride film. Although this tiny amount of oxygen or titanium does not influence formation of silicide, it is supposed that this oxygen or this titanium has functions of pinning movement of cobalt atoms in the cobalt film. According to this mechanism, the path for supplying cobalt atoms from the side wall insulating films of the gate electrode to the poly-silicon gate electrode is blocked, and hence it is possible to prevent formation of high resistance CoSi on the poly-silicon gate electrode pattern.

According to the present invention, the method of producing a semiconductor device having a gate width less than 50 nm includes the steps of forming a poly-silicon gate electrode pattern having a gate width less than 50 nm on a semiconductor substrate; forming a first diffusion region and a second diffusion region on two respective sides of the poly-silicon gate electrode pattern in the semiconductor substrate; depositing a cobalt film on the semiconductor substrate so as to cover the first diffusion region, the second diffusion region, and the poly-silicon gate electrode pattern; depositing a titanium nitride film on the cobalt film; and inducing a reaction between the cobalt film and surfaces of the first diffusion region, the second diffusion region, and the poly-silicon gate electrode pattern after the step of depositing the titanium nitride film so as to form a CoSi₂ film. In this process, the titanium nitride film is formed to have an amorphous phase. Due to this, it is possible to prevent formation of a columnar structure in the titanium nitride film, and prevent diffusion of oxygen atoms through the titanium nitride film. As a result, it is possible to prevent diffusion of the oxygen atoms into the cobalt film, and prevent formation of a non-uniform silicide caused by presence of oxides.

According to the present invention, the method of producing a semiconductor device having a gate width less than 50 nm includes the steps of forming a poly-silicon gate electrode pattern having a gate width less than 50 nm on a semiconductor substrate; forming a first diffusion region and a second diffusion region on two respective sides of the poly-silicon gate electrode pattern in the semiconductor substrate; depositing a cobalt film on the semiconductor substrate so as to cover the first diffusion region, the second diffusion region, and the poly-silicon gate electrode pattern; depositing a titanium nitride film having a composition of TiₓN_{y} (x+y=1) on the cobalt film; and inducing a reaction between the cobalt film and surfaces of the first diffusion region, the second diffusion region, and the poly-silicon gate electrode pattern after the step of depositing the titanium nitride film so as to form a CoSi₂ film. In this process, the composition of the titanium nitride film satisfies x>y.

Due to this, a tiny amount of titanium atoms can diffuse from the titanium nitride film to the cobalt film, and the titanium atoms entering into the cobalt film reduces the native oxide film on the silicon surface. As a result, the reaction for forming silicide takes place uniformly on the silicon surface, and this prevents fluctuations of the sheet resistance. In addition, by enriching the titanium composition in the titanium nitride film, a nano-grain structure is formed in the titanium film and this prevents formation of a columnar structure in the titanium nitride film.

According to the present invention, the semiconductor device of the present invention includes a semiconductor substrate; a poly-silicon gate electrode pattern having a gate width less than 50 nm formed on the semiconductor substrate with a gate insulating film in between; and a first diffusion region and a second diffusion region in the semiconductor substrate on two respective sides of the poly-silicon gate electrode pattern and on respective outer sides of sidewall insulating films of the poly-silicon gate electrode. In the semiconductor device of the present invention, a CoSi₂ film is formed on surfaces of the first diffusion region, the second diffusion region, and the poly-silicon gate electrode pattern, and an atomic percentage of titanium in the CoSi₂ film is in a range from 0.1% to 1%. Due to this, it is possible to promote the reduction reaction for forming the CoSi2 layer in the salicide process without inducing an increase of the specific resistance of the CoSi₂ layer and abnormal growth of CoSi₂ at the edge of the element separation region of the STI structure, and a uniform low resistance CoSi₂ layer can be formed.

These and other objects, features, and advantages of the present invention will become more apparent from the following detailed description of the preferred embodiments given with reference to the accompanying drawings.

### BRIEF DESCRIPTION OF THE DRAWINGS

FIG. 1 is a cross-sectional view of a semiconductor device having a silicide layer in the related art;

FIGS. 2A through 2C are cross-sectional views illustrating a method of fabricating the semiconductor device in FIG. 1 by the salicide process;

FIGS. 3A through 3C, continuing from FIG. 2C, are cross-sectional views illustrating the method of fabricating the semiconductor device in FIG. 1 by the salicide process;

FIG. 4 is a diagram showing a relation between a gate width and a sheet resistance of a gate electrode;

FIG. 5 is a cross-sectional view of the a portion of a gate electrode;

FIG. 6 is a phase equilibrium diagram of a Co—Si system;

FIGS. 7A and 7B, corresponding to FIG. 2C and FIG. 3C, respectively, are cross-sectional views of a gate electrode having a large gate width, showing a process of forming the silicide;

FIGS. 8A and 8B, corresponding to FIG. 2C and FIG. 3C, respectively, are cross-sectional views of a gate electrode having a small gate width, showing a process of forming the silicide;

FIG. 9 is a diagram for explaining the principle of the present invention;

FIG. 10 shows X-ray diffraction spectra of titanium nitride films formed by sputtering and having different film thicknesses;

FIG. 11 presents results of sheet resistances of the CoSi₂ layers in the structure in FIG. 9 with the thickness of the TiN protection film being changed;

FIG. 12, corresponding to FIG. 8A, is a cross-sectional view of the gate electrode for additional explanation of the principle of the present invention;

FIG. 13 shows X-ray diffraction spectra of titanium nitride films formed under usual sputtering conditions and titanium nitride films having nonstoichiometric compositions for comparison with that of a metal film;

FIG. 14 presents results of a comparison between the fluctuation of the sheet resistances of the CoSi₂ layer in the structure in FIG. 9 obtained with a 50 nm TiN film as the protection film, and the fluctuation of the sheet resistances of the CoSi₂ layer formed under the usual sputtering conditions;

FIGS. 15A through 15C are cross-sectional views illustrating a method of fabricating a MOS transistor according to embodiments of the present invention;

FIGS. 16A through 16C, continuing from FIG. 15C, are cross-sectional views illustrating the method of fabricating the MOS transistor according to embodiments of the present invention.

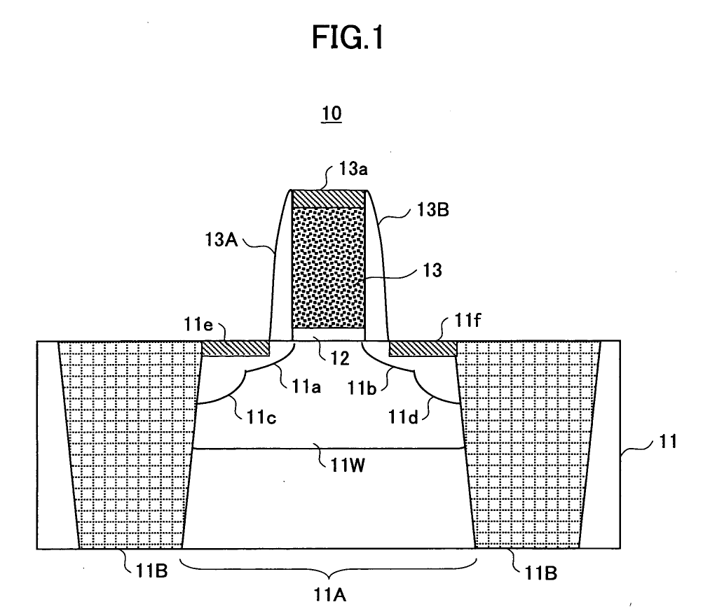

### DESCRIPTION OF THE PREFERRED EMBODIMENTS

[Principle]

In a recent high speed semiconductor device which is miniaturized and fabricated based on a design rule of 130 nm, or 90 nm, or, moreover, 65 nm, the gate width turns to be less than 50 nm, for example, it is 40 nm or shorter.

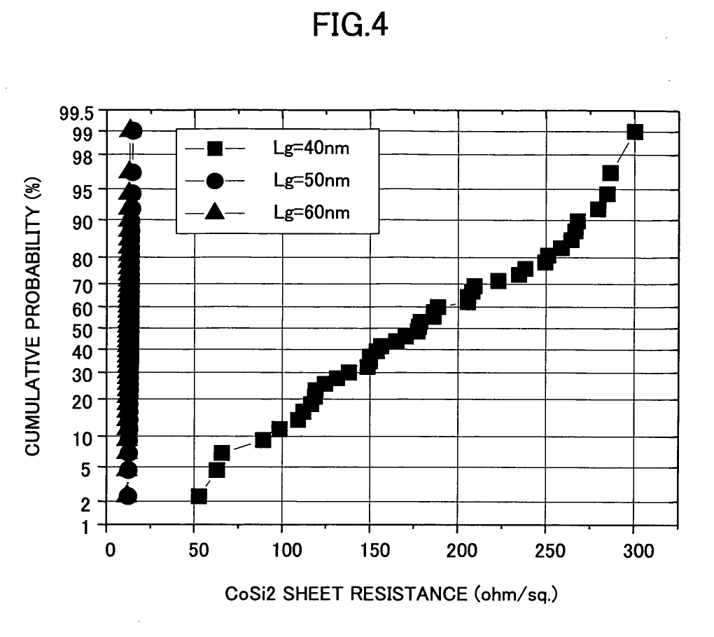

When the gate width is less than 50 nm in the miniaturized semiconductor device, as illustrated in FIG. 4, even if CoSi₂ is used, the sheet resistance of the gate electrode fluctuates remarkably.

FIG. 4 is a diagram showing a relation between the gate width and the sheet resistance of the gate electrode.

In FIG. 4, the abscissa represents the sheet resistance of the CoSi₂ layer, and the ordinate represents a cumulative probability. As illustrated in FIG. 4, when the gate width Lg is 60 nm and 50 nm, the sheet resistance essentially does not fluctuate. In contrast, when the gate width Lg becomes shorter than 50 nm, for example, when the gate width Lg is 40 nm, it is found that the sheet resistance fluctuates greatly.

Although it is still not clearly elucidated why fluctuations of the sheet resistance characteristically occur when the gate electrode is highly miniaturized, it is considered that probably this problem is related to the following phenomena, that is, (1) aggregation of CoSi₂ caused by the increasing influence of impurities on the silicon surface, especially, native oxide films on formation of CoSi₂, and by these increases of influence occurring along with reduction of the area of the silicon surface on which the CoSi₂ film is formed, (2) diffusion of residual oxygen atoms, produced in thermal treatment, into the cobalt film, and oxidation of the cobalt film by the oxide, and (3) lack of silicon required for forming CoSi₂ layers due to reduction of the area of the silicon surface.

To solve the problem related to reason (1), it may be tried to strongly clean the surfaces of the source region 11c, the drain region 11d, and the poly-silicon gate electrode 13 before depositing the cobalt film. However, by the over-cleaning, sidewall insulating films 13A and 13B of the poly-silicon gate electrode 13 may be etched, and this results in an increased leakage current between the gate electrode 13 and the source region 11c, and between the gate electrode 13 and the drain region 11d.

To solve the problem related to reason (2), it may be tried to use a titanium film, instead of the TiN film 15, as a cap film. However, when depositing a titanium film on the cobalt film as the cap film 15, abnormal growth of CoSi₂ is apt to occur at the edge of the element separation region 11B of the STI structure, and this results in an increase of a junction leakage current.

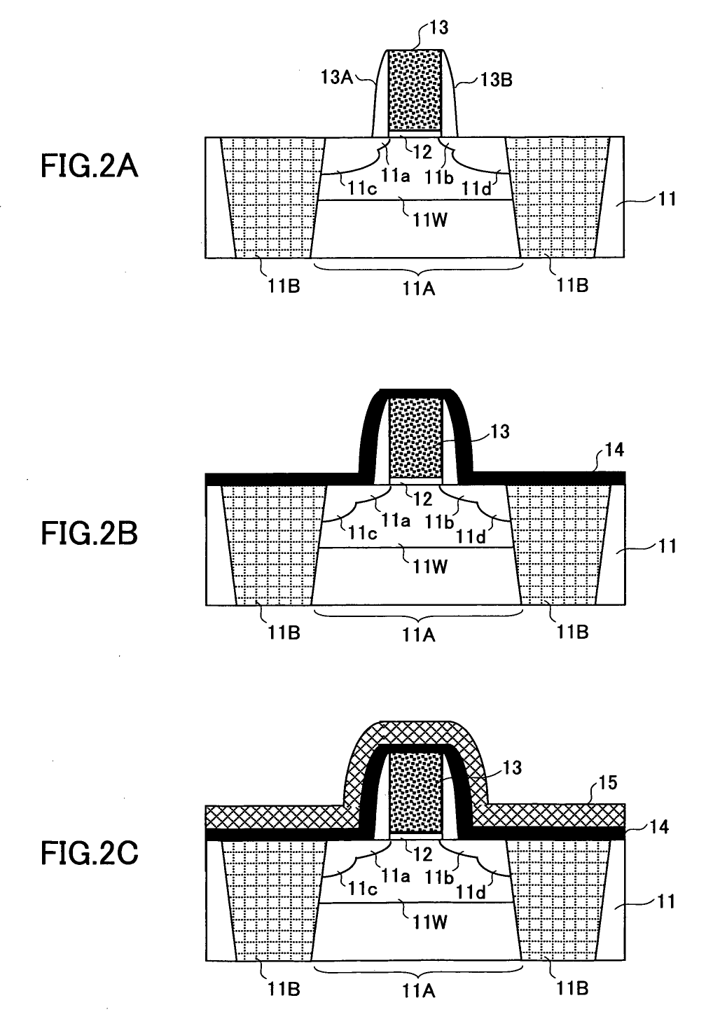

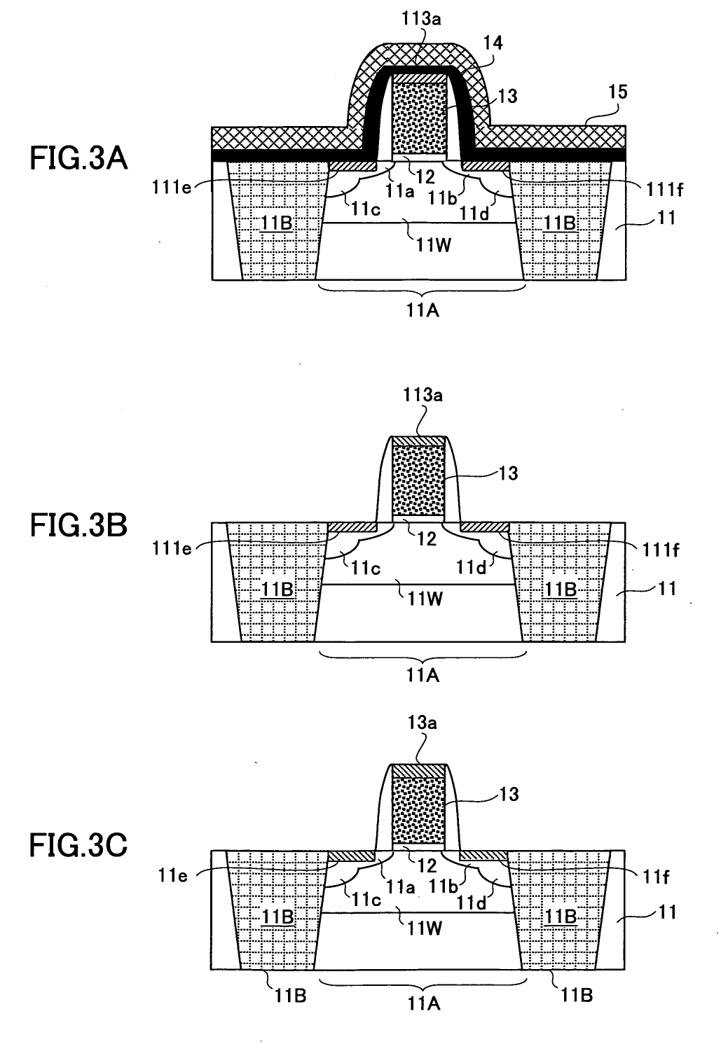

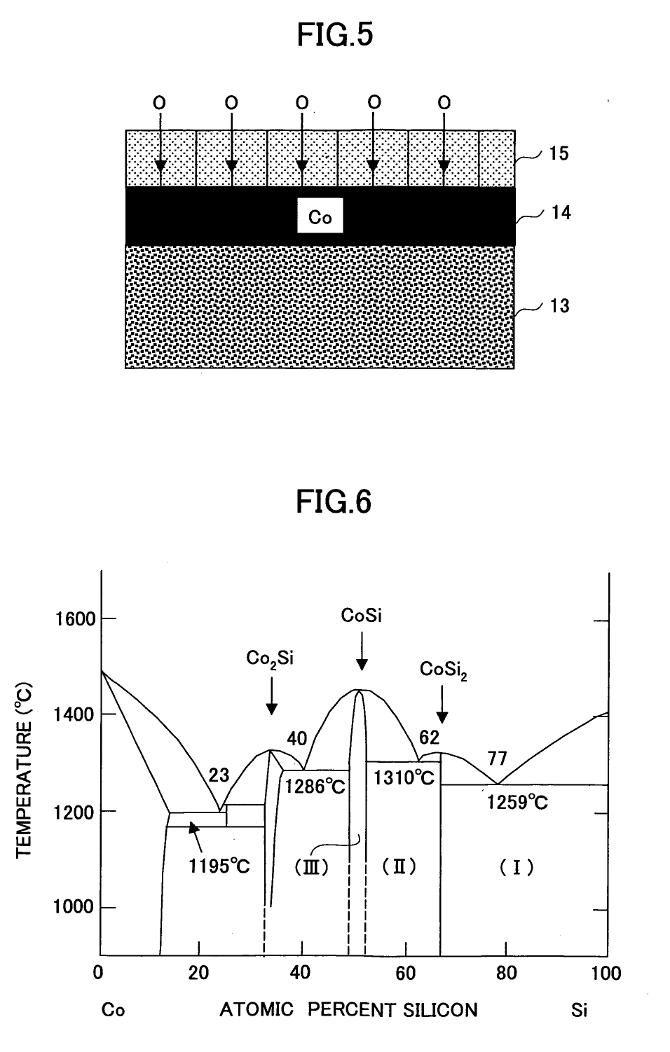

FIG. 5 is a cross-sectional view of the upper portion of the gate electrode 13 at a stage between the step in FIG. 2C and the step in FIG. 3A.

In FIG. 5, a TiN film is used as the cap film 15. As illustrated in FIG. 5, the TiN film 15 has a columnar structure, and due to this, the residual oxygen atoms diffuse into the TiN film 15 along the boundaries of TiN crystal grains, and can easily arrive at the cobalt film. This may cause formation of a non-uniform CoSi₂ layer.

Next, reason (3) is discussed.

FIG. 6 is a phase equilibrium diagram of a Co—Si system.

FIG. 6 shows that three types of silicide compounds may exist in the Co—Si system, that is, Co₂Si, CoSi, and CoSi₂. These silicides are converted to each other through the following reactions.
Co/Si→Co₂Si
Temperature: 300-400° C.,
Diffusion seed: Co
Co₂Si→CoSi
Temperature: 450-550° C.,
Diffusion seed: Si
CoSi→CoSi₂
Temperature: 600° C.,
Diffusion seed: Co

In these reactions, only CoSi₂ has a low specific resistance (15-25 μΩcm).

In FIG. 6, if the Co—Si system has a silicon rich composition (I), according to the above chemical formulae, even if the Co₂Si phase or the CoSi phase is formed temporarily during the reaction, these phases are meta-stable phases, and ultimately a composition including coexisting CoSi₂ and Si is obtainable.

Contrary to this, in a Co rich composition (II), the CoSi phase and the CoSi₂ phase co-exist. Moreover, in a composition (III) including richer Co, the CoSi having a high resistance becomes a main phase.

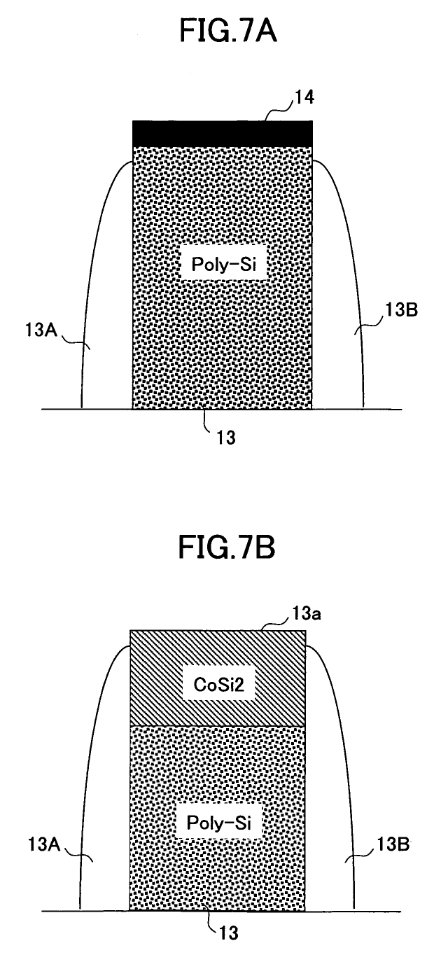

FIGS. 7A and 7B, corresponding to FIG. 2C and FIG. 3C, respectively, are cross-sectional views of the gate electrode 13 having a large gate width, showing a process of forming the silicide.

As illustrated in FIG. 7A and FIG. 7B, if the gate width of the poly-silicon gate electrode 13 is sufficiently long, even when the cobalt film 14 deposited on the poly-silicon gate electrode 13 is reacted completely, there is still a sufficient amount of silicon existing in the poly-silicon gate electrode 13 for forming CoSi₂. As a result, if the structure in FIG. 7A is processed by thermal treatment at a temperature from 600° C. to 700° C., as illustrated in FIG. 7B, the low resistance CoSi2 silicide film 13a is formed on the poly-silicon gate electrode 13.

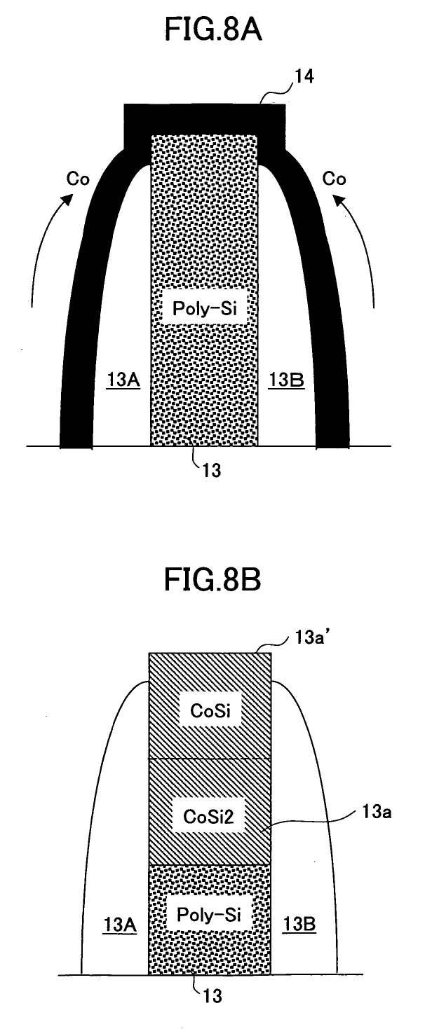

FIGS. 8A and 8B, corresponding to FIG. 2C and FIG. 3C, respectively, are cross-sectional views of the gate electrode 13 having a small gate width, showing a process of forming the silicide.

As illustrated in FIG. 8A and FIG. 8B, if the gate width of the poly-silicon gate electrode 13 is less than 50 nm, not only the portion of the cobalt film 14 deposited on the poly-silicon gate electrode 13, but also the portion of the cobalt film 14 deposited on the sidewall insulating films 13A and 13B contribute to the reaction for forming the silicide film, and due to the diffusion effect of cobalt as indicated in FIG. 8A, the latter contribution is not negligible.

As a result, during the thermal treatment at a temperature from 600° C. to 700° C., as illustrated in FIG. 8B, a thick silicide film is formed on the poly-silicon gate electrode 13. Among the thus formed silicide film portions, the portion 13a of the silicide film in contact with the poly-silicon of the poly-silicon gate electrode 13 has a low resistance, but the upper portion 13a′ of the formed silicide film, which is apart from the poly-silicon, may have a high resistance, because at the upper portion 13a′ of the formed silicide film, the absolute number of silicon atoms decreases along with reduction of the gate width, and further, because of diffusion of cobalt atoms from a portion of the cobalt film 14 covering the sidewall insulating films 13A and 13B, silicon becomes poor but cobalt becomes rich, and this results in formation of the high resistance CoSi silicide layer 13a′.

Namely, the fluctuations of the sheet resistance as explained with reference to FIGS. 2A through 2C may be caused by irregular formation of such high resistance CoSi silicide layers 13a′.

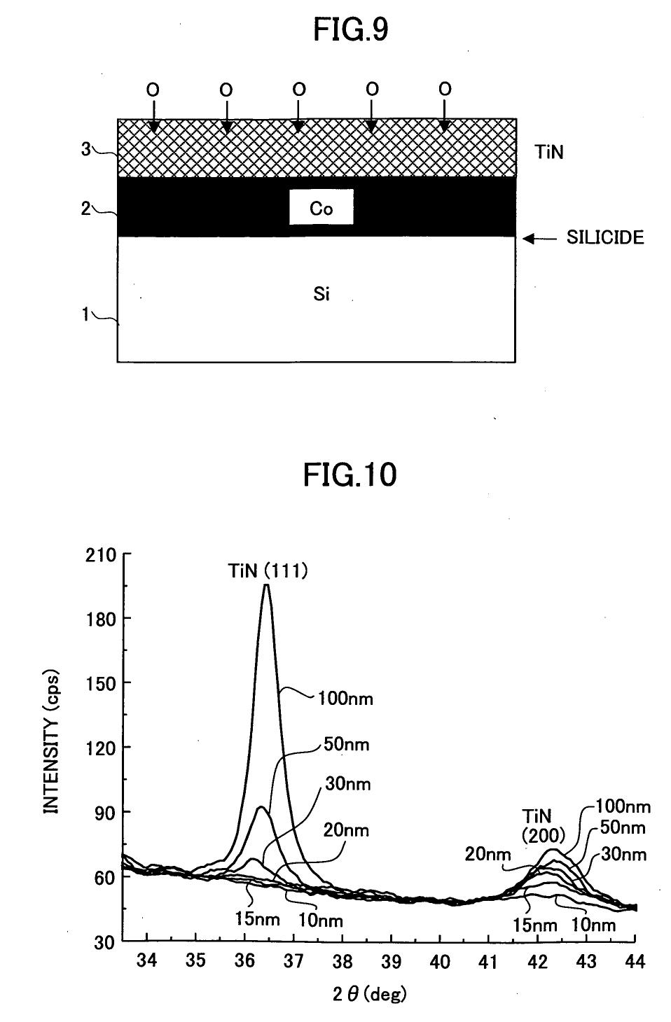

FIG. 9 is a diagram for explaining the principle of the present invention.

Referring to FIG. 9, when forming a silicide layer by reactions between a cobalt film 2 and a silicon surface 1 of a diffusion region, or a poly-silicon gate electrode, a titanium nitride film 3 deposited on the cobalt film 2 is formed to be an amorphous film or a film having a nano-grain structure, but not a film having the columnar structure as illustrated in FIG. 5. In the nano-grain structure, the diameter of the crystal grains in the titanium nitride film is formed to be less than the thickness of the titanium nitride film, preferably, about 10 nm or less.

Due to this structure, essentially these are not crystal grain boundaries continuously extending from one side of the film to the other side of the film, as illustrated in FIG. 5, so that it is possible to effectively prevent diffusion of oxygen atoms into the cobalt film 2 through the titanium nitride film 3, and effectively prevent formation of native oxide films on the silicon surface 1 and fluctuations of the sheet resistance of the silicide film concurrently occurring with the formation of the native oxide films.

Such a titanium nitride film 3 having an amorphous phase or a nano-grain structure can be fabricated by reducing the film thickness when forming the film.

FIG. 10 shows X-ray diffraction spectra of titanium nitride films which are formed by sputtering and have different film thicknesses.

When forming the titanium nitride films shown in FIG. 10 by sputtering, sputtering power is set to be 9 kW, and in a sputtering atmosphere including nitrogen gas (N₂) and argon gas (Ar), the ratio of the flow rate of N₂ to that of Ar (namely, SCCM ratio) being set to be 90/50.

When the film thickness is less than 20 nm, it is found that a TiN (111) diffraction peak is not observed at all. Whereas, when the film thickness exceeds 30 nm, it is found that the TiN (111) diffraction peak turns to be observable, indicating that crystallization proceeds in the film. The same is true for the TiN (200) diffraction peak.

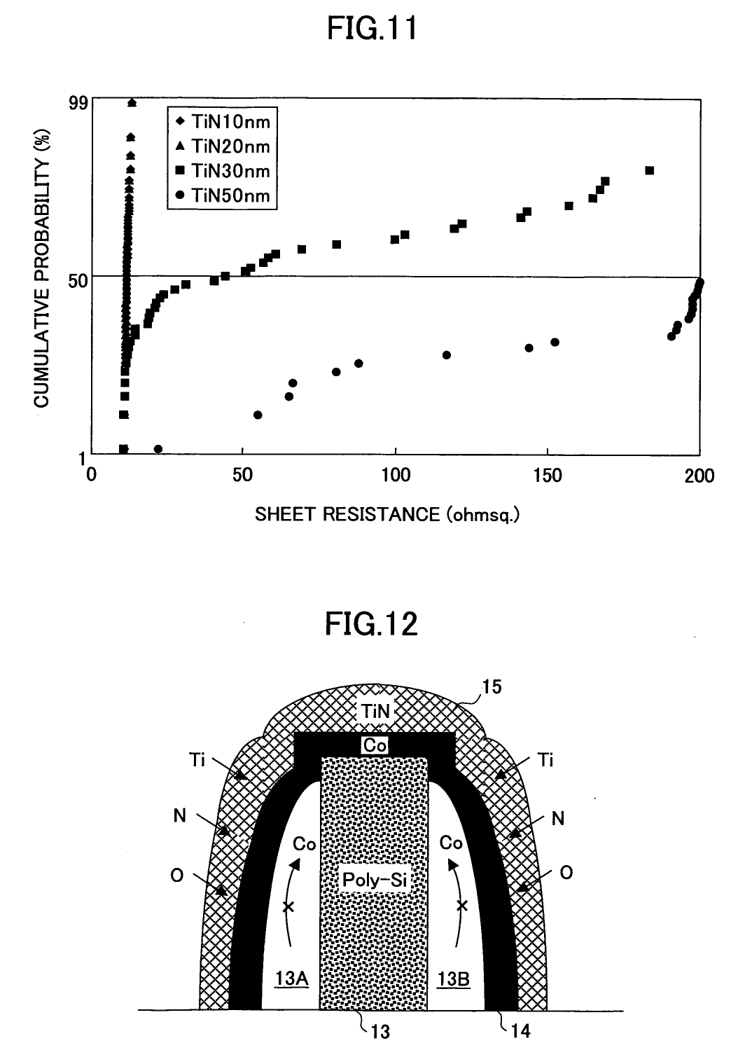

FIG. 11 presents results of the sheet resistances of the CoSi₂ layers in the structure in FIG. 9 with the thickness of the TiN protection film 13 being changed.

Referring to FIG. 11, it is found that when the film thickness of the TiN protection film 13 in the silicide process is 10 nm or 20 nm, the fluctuation of the sheet resistance is essentially not observed, while, when the film thickness of the TiN protection film 13 is 30 nm or more, the fluctuation of the sheet resistance increase drastically.

The results presented in FIG. 11 indicate that if the TiN protection film 13 is formed to have a film thickness less than 30 nm, preferably, equal to or less than 20 nm, the nano-structure is formed in the TiN protection film 13, and in thermal treatment for forming the silicide, diffusion of residual oxygen atoms in the atmosphere into the cobalt film 12 through the titanium nitride film 13 can be prevented effectively.

On the other hand, if the TiN protection film 13 is formed to have a film thickness less than 20 nm, for example, to be a few nanometers, as described above, the TiN protection film 13 has a nano-grain structure or an amorphous phase. As a result, probably, the titanium atoms in the TiN film 13 may diffuse into the underlying cobalt film 12. Further, this very thin TiN film 13 cannot completely block diffusion of the residual oxygen atoms in the atmosphere into the cobalt film 12, and a small amount of oxygen atoms may enter into the cobalt film 12.

If oxygen atoms or titanium atoms enter into the cobalt film 12, although this small amount of oxygen or titanium impurities does not influence formation of silicide, these oxygen or titanium atoms have functions of pinning movement of cobalt atoms in the cobalt film 12.

FIG. 12, corresponding to FIG. 8A, is a cross-sectional view of the gate electrode 13, continuously showing the principle of the present invention.

As illustrated in FIG. 12, because the small amount of oxygen or titanium impurities does not influence formation of silicide, in a portion of the cobalt film 14 covering the sidewall insulating films 13A and 13B of the poly-silicon gate electrode 13, these impurities prevent supply of cobalt atoms to the poly-silicon gate electrode on which silicide is to be formed. Hence, in a miniaturized semiconductor device, when the total amount of silicon atoms required for forming a low resistance CoSi₂ layer is insufficient due to reduction of the gate width of the poly-silicon gate electrode 13, by utilizing the configuration of the present invention, it is possible to suppress the supply of cobalt atoms, and avoid the problem of high resistance CoSi remaining not to transform to the CoSi₂ phase on the poly-silicon gate electrode 13 by the reactions for forming silicide, and the sheet resistance of the CoSi₂ phase fluctuating.

In addition, the present invention further provides a technique of forming the titanium nitride film 3, which is arranged in the model structure in FIG. 9, so that the titanium nitride film 3 has a nonstoichiometric composition TiₓN_{y} (x+y=1) with the titanium composition being enriched so as to reduce non-uniformity of the silicide formation reaction.

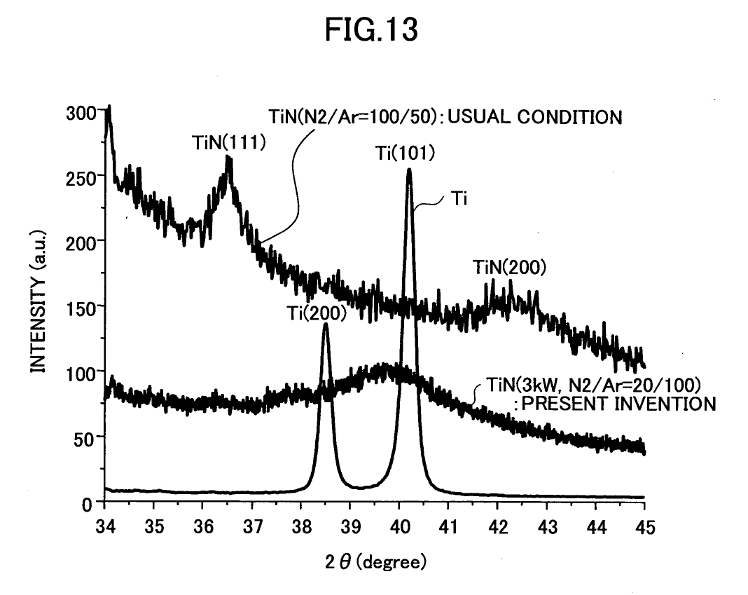

FIG. 13 shows X-ray diffraction spectra of titanium nitride films formed under usual sputtering conditions and titanium nitride films having nonstoichiometric compositions for comparison with that of a metal film.

Referring to FIG. 13, as the usual sputtering conditions, sputtering power is set to be 9 kW, and as the sputtering atmosphere, nitrogen gas (N₂) is supplied with a rate of flow of 100 SCCM, and argon gas (Ar) is supplied with a rate of flow of 50 SCCM. Under these conditions, when the film thickness is formed to be 30 nm, it is confirmed that a clear TiN (111) diffraction peak and an unclear TiN (200) diffraction peak appear.

In contrast, when forming the TiN film 3 by sputtering according to the present invention, the acceleration voltage is set to be 3 keV, nitrogen gas (N₂) is supplied with a flow rate of 20 SCCM, and argon gas (Ar) is supplied with a flow rate of 100 SCCM. Under these conditions, the TiN (111) diffraction peak and the TiN (200) diffraction peak are not observed at all. In other words, the observation indicates that the TiN film formed under these conditions has an amorphous phase.

In the structure shown in FIG. 9, when the amorphous TiN film with titanium being enriched is used as a protection film to form the silicide, the titanium atoms are supplied from the TiN protection film to the cobalt film 2, and these titanium atoms reduce the native oxide film on the interface between the silicon surface 1 and the cobalt film 2. Further, as described above, the titanium atoms entering into the cobalt film 2 have the function of pinning movement of cobalt atoms in the cobalt film 2, and have the effect of effectively suppressing the supply of cobalt atoms to the upper portion of the poly-silicon gate electrode 13 where silicide is formed.

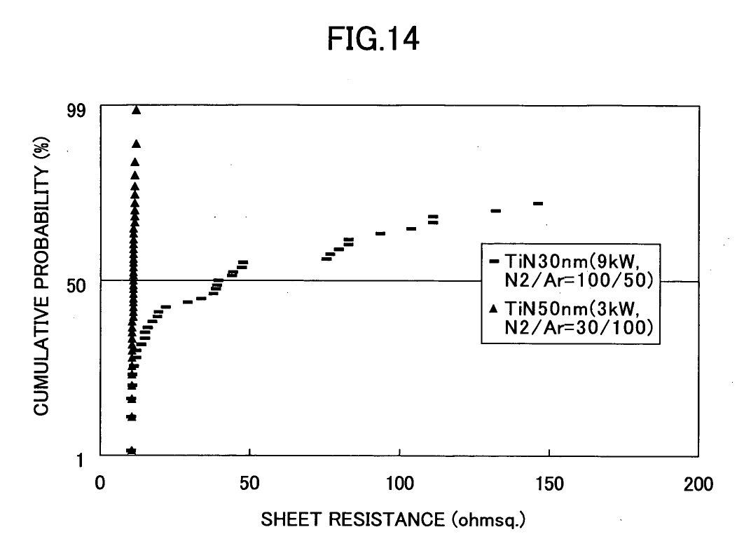

FIG. 14 presents results of a comparison between the fluctuation of the sheet resistances of the CoSi₂ layer in the structure in FIG. 9 obtained with a 50 nm TiN film 13 as the protection film, and the fluctuation of the sheet resistances of the CoSi₂ layer formed under the aforesaid usual sputtering conditions.

Referring to FIG. 14, if the silicide film is formed under the conditions of the present invention with a Ti-enriched amorphous TiN film 3 as the protection film 3, it is found that even when the film thickness of the TiN protection film 13 is 50 nm, the sheet resistance essentially does not fluctuate. While, under the usual sputtering conditions, it is found that the sheet resistance begins to fluctuate even when the film thickness of the TiN protection film 13 is 30 nm.

If the atomic percentage of titanium in the cobalt film is greater than 1%, the specific resistance of the obtained CoSi₂ layer increases, and abnormal growth of CoSi₂ occurs at the edge of the element separation region 11B of the STI region, and this results in an increase of a leakage current. In addition, if the atomic percentage of titanium in the cobalt film is too low, the aforementioned reduction reaction of the native oxide film on the silicon surface by the titanium atoms is suppressed, and the fluctuation of the sheet resistances cannot be reduced. For this reason, it is preferable that the composition of the titanium nitride film be chosen such that the atomic percentage of titanium in the CoSi₂ film is in a range from 0.1% to 1%.

Corresponding to such a composition of the titanium nitride film, in the present invention, when the TiN film is formed to have a nonstoichiometric composition TiₓN_{y} (x+y=1) with the titanium composition being enriched, it is preferable that the composition of the titanium nitride film satisfy 1.0<x/y<5.0.

When the TiN film is formed by sputtering, the composition ratio of Ti/N in the TiN film can be changed by adjusting the ratio of concentrations of nitrogen and argon in the sputtering atmosphere. This technique is described in reference 5. In addition, in order to form an amorphous TiN film or a TiN film having a nano-grain structure, a substrate bias may be applied when forming the film by sputtering, as described in references 6 and 7, or by reducing the thickness of the TiN film, as described in reference 8.

Below, based on the above principle, preferred embodiments of methods for producing the semiconductor device according to the present invention are explained with reference to the accompanying drawings.

### First Embodiment

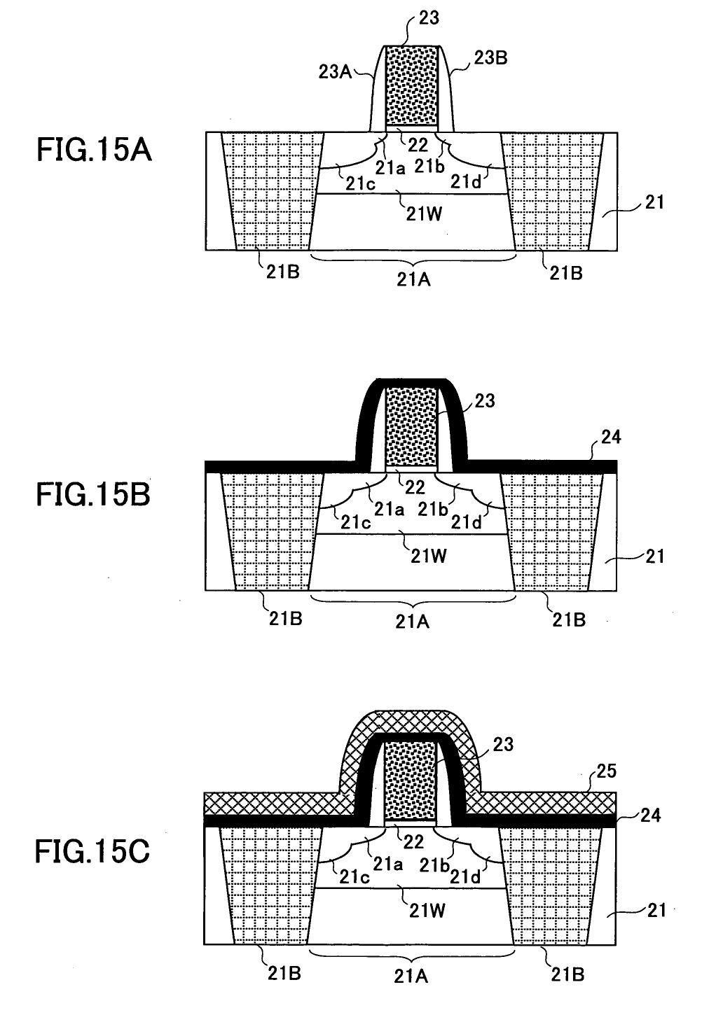

FIGS. 15A through 15C are cross-sectional views illustrating a method of fabricating a MOS transistor according to a first embodiment of the present invention.

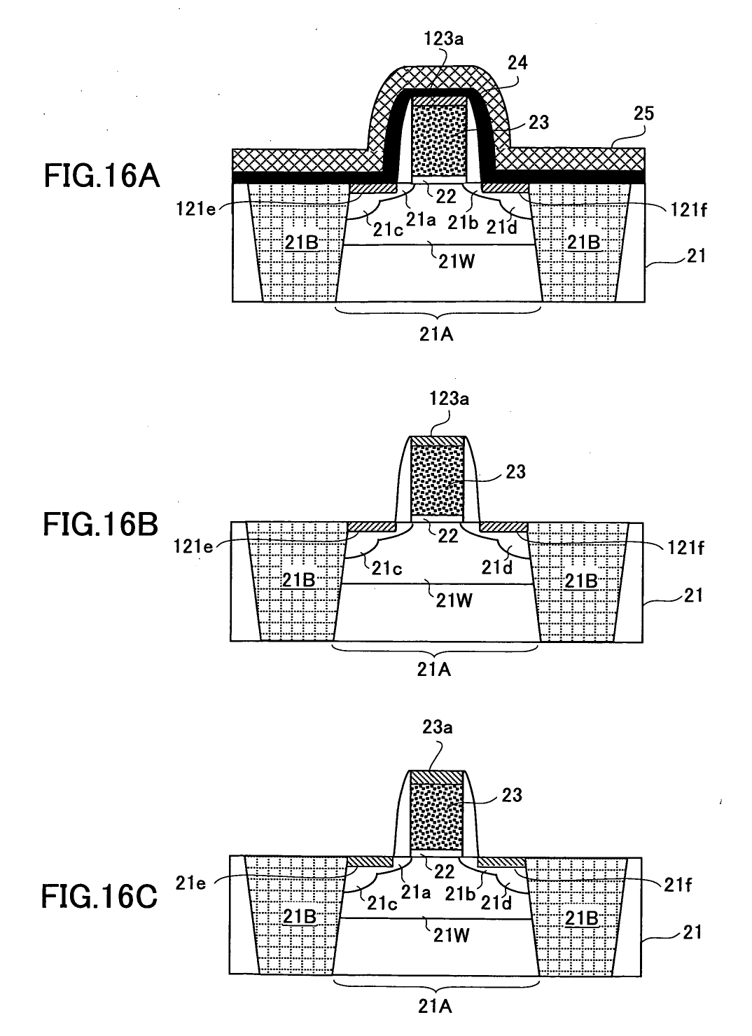

Continuing from FIG. 15C, FIGS. 16A through 16C are cross-sectional views illustrating the method of fabricating the MOS transistor according to the first embodiment of the present invention.

In the step illustrated in FIG. 15A, typically, on a p-type silicon substrate 21, an element region 21A is defined by STI (shallow trench isolation) element separation regions 21B, and a p-type or n-type well 21W is formed in the element region 21A.

In addition, in the element region 21A, a poly-silicon gate electrode 23 is formed on the silicon substrate 21, for example, having a height of 100 nm and a gate width equal to or less than 50 nm, and with a gate insulating film 22 formed from, for example, a 2 nm silicon oxide film or nitride film in between.

When the MOS transistor is an n-channel MOS transistor, the poly-silicon gate electrode 23 is doped to be n-type, for example, by ion implantation of P⁺ ions with a dose of 1×10¹⁶ cm⁻² and an acceleration voltage of 10 keV. When the MOS transistor is a p-channel MOS transistor, the poly-silicon gate electrode 23 is doped to be p-type, for example, by ion implantation of B⁺ ions with a dose of 1×10¹⁶ cm⁻² and an acceleration voltage of 5 keV.

In addition, in the element region 21A, when the MOS transistor is an n-channel MOS transistor, the surface of the silicon substrate 21 is doped to be p-type, for example, by ion implantation of B⁺ ions with a dose of 1×10¹³ cm⁻² and an acceleration voltage of 15 keV. When the MOS transistor is a p-channel MOS transistor, the surface of the silicon substrate 21 is doped to be n-type, for example, by ion implantation of As⁺ ions with a dose of 1×10¹³ cm⁻² and an acceleration voltage of 80 keV.

In addition, in the element region 21A, in the silicon substrate, at two sides of the poly-silicon gate electrode 23, n-type or p-type diffusion regions 21a and 21b are formed as a source extension region 21a and a drain extension region 21b.

When the MOS transistor is an n-channel MOS transistor, the source extension region 21a and the drain extension region 21b can be formed by doping, for example, As⁺ by ion implantation with a dose of 1×10¹⁵ cm⁻² and an acceleration voltage of 1 keV. When the MOS transistor is a p-channel MOS transistor, the source extension region 21a and the drain extension region 21b can be formed by doping, for example, B⁺ by ion implantation with a dose of 5×10¹⁵ cm⁻² and an acceleration voltage of 0.5 keV.

After the source extension region 21a and the drain extension region 21b are formed, for example, a 100 nm oxide film is deposited by CVD on the silicon substrate 21 so as to cover the poly-silicon gate electrode 23, and the oxide film is etched back by RIE, thereby, sidewall insulating films 23A and 23B are formed on two side walls of the poly-silicon gate electrode 23, respectively.

In the structure shown in FIG. 15A, with the gate electrode 23, and the sidewall insulating films 23A and 23B as masks, a source region 21c is formed by ion implanting of n-type or p-type impurities, which partially overlaps with the source extension region 21a and has the same conductivity as the source extension region 21a, and a drain region 21d is formed by ion implanting of n-type or p-type impurities, which partially overlaps with the drain extension region 21b and has the same conductivity as the drain extension region 21b.

When the MOS transistor is an n-channel MOS transistor, the source region 21c and the drain region 21d can be formed by doping, for example, P⁺ by ion implantation with a dose of 1×10¹⁶ cm⁻² and an acceleration voltage of 10 keV. When the MOS transistor is a p-channel MOS transistor, the source region 21c and the drain region 21d can be formed by doping, for example, B⁺ by ion implantation with a dose of 1×10¹⁵ cm⁻² and an acceleration voltage of 5 keV.

In the step illustrated in FIG. 15B, the structure in FIG. 15A is processed by hydrofluoric acid treatment to remove native oxide films on the surfaces of the gate electrode 23, and the source/drain regions 21c, 21d. Further, a cobalt film 24 is deposited to a thickness of 6 nm by sputtering by using a cobalt target. It should be noted that the method of forming the cobalt film 24 is not limited to sputtering, and other deposition methods such as electron beam evaporation can also be used. Here, considering the specific resistance of the silicide layer to be formed, preferably, the thickness of the cobalt film 24 is set to be 4 to 7 nm.

In the step illustrated in FIG. 15C, a titanium nitride film 25, as a protection film, is formed to 30 nm by sputtering on the structure in FIG. 15B. In the sputtering process, the sputtering power is set to be 9 kW, and in a sputtering atmosphere including nitrogen gas (N₂), argon gas (Ar), the ratio of the flow rate of N₂ to that of Ar (namely, SCCM ratio) is set to be 90/50, and the substrate bias is set to be −100 V. The substrate bias is adjusted so that the deposition speed of the titanium nitride is greater than 90% and less than 99% of the deposition speed of the titanium nitride when a substrate bias is not applied. When the substrate bias is set to be low, the obtained titanium nitride film 25 has the nano-grain structure, while if the substrate bias is set to be high, as in this embodiment, the obtained titanium nitride film 25 has the amorphous phase. In other words, in the present embodiment, by setting the substrate bias applied when depositing the titanium nitride film 25 to be relatively high, the obtained titanium nitride film 25 has the amorphous phase as described in FIG. 10.

In the step illustrated in FIG. 16A, rapid thermal annealing (RTA) is executed on the structure obtained in FIG. 15C at a temperature of 480° C. for 30 seconds, and CoSi layers 121e, 121f, and 123a are formed on the interfaces between the cobalt film 24 and the source region 21c, the drain region 21d, and the poly-silicon gate electrode 23, respectively. The step of forming the silicide layers in FIG. 16A may also be performed by furnace annealing instead of RTA, or by both furnace annealing and RTA.

In the step illustrated in FIG. 16B, wet etching is executed on the structure obtained in FIG. 15C for 20 minutes with the ratio of sulfuric acid to hydrogen peroxide to be 3:1, to selectively remove the titanium nitride film 25, and un-reacted cobalt film 24 on insulating films such as the element separation regions 21B, and the sidewall insulating films 23A and 23B.

In the step illustrated in FIG. 16C, a second rapid thermal annealing (RTA) is executed at a temperature of 750° C. for 30 seconds to convert the previously formed CoSi layers 121e, 121f, and 123a to CoSi₂ layers 21e, 21f, and 23a. Here, the step of RTA in FIG. 16C may also be replaced by a thermal treatment performed at a temperature from 650° C. to 750° C. for 10 to 120 seconds, or by a spike annealing at a temperature from 800° C. to 1000° C.

After the step illustrated in FIG. 16C, a SiN etching stopper film is formed on the structure in FIG. 16C, and further an interlayer insulating film is formed. After that, contact holes are formed to expose the CoSi₂ layers 21e, 21f, and 23a on the source region 21c, the drain region 21d, and the poly-silicon gate electrode 23, and the contact holes are further filled with via plugs.

According to the present embodiment, in the step in FIG. 15C, because the titanium nitride film 25 is formed to have the nano-grain structure or have the amorphous phase, the CoSi₂ layers 21e, 21f, and 23a can be formed uniformly on surfaces of the source region 21c, the drain region 21d, and the poly-silicon gate electrode 23a, without diffusion of the residual oxygen atoms-existing in the atmosphere used in thermal treatment into the cobalt film 24, and without formation of new oxide films on the silicon surfaces where the silicide layers are to be formed, as described with reference to the model structure in FIG. 9. Consequently, as described with reference to FIG. 11 through FIG. 14, the CoSi₂ layers 21e, 21f, and 23a have uniform sheet resistances with small fluctuations.

### Second Embodiment

In the second embodiment, a semiconductor device is fabricated by a method basically the same as that illustrated in FIGS. 15A through 15C, and FIGS. 16A through 16C, except that in the step illustrated in FIG. 15C in the present embodiment, the titanium nitride protection film 25 is formed to 30 nm by sputtering with the sputtering power to be 3 kW, and the flow rate of N₂ to be 20 sccm, the flow rate of Ar to be 100 sccm, that is, the SCCM ratio of N₂/Ar is set to be 20/100. Here, the sputtering power and the SCCM ratio of N₂/Ar are adjusted so that the Ti/N composition ratio is 1 to 5, and the thus obtained titanium nitride protection film 25 is amorphous with titanium being enriched.

After the titanium nitride film 25 is formed in the step in FIG. 15C, in the step illustrated in FIG. 16A, the same as the first embodiment, a first rapid thermal annealing (RTA) is executed at a temperature of, for example, 480° C. for 30 seconds, and CoSi layers 121e, 121f, and 123a are formed on the surfaces of the source region 21c, the drain region 21d, and the poly-silicon gate electrode 23, respectively.

Similar to the first embodiment, the step of forming the silicide layers in FIG. 16A may also be performed by furnace annealing instead of RTA, or by both furnace annealing and RTA.

Next, in the step illustrated in FIG. 16B, wet etching is executed to selectively remove the titanium nitride film protection film 25 and un-reacted cobalt film 24 on insulating films such as the element separation regions 21B and the sidewall insulating films 23A and 23B.

Further, in the step illustrated in FIG. 16C, a second rapid thermal annealing (RTA) is executed at a temperature of 750° C. for 30 seconds to convert the previously formed CoSi layers 121e, 121f, and 123a to CoSi₂ layers 21e, 21f, and 23a.

Similar to the first embodiment, the step of RTA in FIG. 16C may also be replaced by a thermal treatment performed at a temperature from 650° C. to 750° C. for 10 to 120 seconds, or by a spike annealing at a temperature from 800° C. to 1000° C.

After the step illustrated in FIG. 16C, a SiN etching stopper film is formed on the structure in FIG. 16C, and further an interlayer insulating film is formed.

According to the present embodiment, in the step in FIG. 15C, because the titanium nitride film 25 is formed to be in the amorphous phase, titanium atoms supplied from the titanium nitride protection film 25 to the cobalt film 24 reduce oxide films on the surfaces of the source region 21c, the drain region 21d, and the poly-silicon gate electrode 23, such as residual native oxide films, and thereby remove these oxide films. Hence, the CoSi₂ layers 21e, 21f, and 23a can be formed uniformly on the surfaces of the source region 21c, the drain region 21d, and the poly-silicon gate electrode 23a. As a result, as described with reference to FIG. 11 or FIG. 14, the CoSi₂ layers 21e, 21f, and 23a have uniform sheet resistances with small fluctuations.

Furthermore, since the diffusion path of oxygen atoms to the titanium nitride protection film 25 is blocked by the amorphous structure, this prevents formation of new oxide films on the silicon surfaces due to the residual oxygen atoms existing in the atmosphere used in thermal treatment, and eliminates the problem of non-uniformity in silicide formation.

Moreover, as described above, the titanium atoms entering into the cobalt film 24 have the function of pinning the movement of cobalt atoms in the cobalt film 24, and have the effect of effectively suppressing the supply of cobalt atoms to the upper portion of the poly-silicon gate electrode 23 where the silicide layer is formed.

### Third Embodiment

In the third embodiment, a semiconductor device is fabricated by a method basically the same as that illustrated in FIGS. 15A through 15C, and FIGS. 16A through 16C, except that in the step illustrated in FIG. 15C in the present embodiment, the titanium nitride protection film 25 is formed to 10 nm by sputtering with the sputtering power to be 9 kW, and the flow rate of N₂ to be 90 sccm, the flow rate of Ar to be 50 sccm, that is, the SCCM ratio of N₂/Ar is set to be 90/50.

In the present embodiment, because the titanium nitride protection film 25 is formed to have a nano-grain structure, the thickness of the titanium nitride protection film 25 is set to be 10 nm. Reference can be made to FIG. 10.

After the titanium nitride film 25 is formed in the step in FIG. 15C, in the step illustrated in FIG. 16A, the same as the previous embodiment, a first rapid thermal annealing (RTA) is executed at a temperature of, for example, 480° C. for 30 seconds, and CoSi layers 121e, 121f, and 123a are formed on the surfaces of the source region 21c, the drain region 21d, and the poly-silicon gate electrode 23, respectively.

Similar to the previous embodiment, the step of forming the silicide layers in FIG. 16A may also be performed by furnace annealing instead of RTA, or by both furnace annealing and RTA.

Next, in the step illustrated in FIG. 16B, wet etching is executed to selectively remove the titanium nitride film protection film 25 and un-reacted cobalt film 24 on insulating films such as the element separation regions 21B and the sidewall insulating films 23A and 23B.

Further, in the step illustrated in FIG. 16C, a second rapid thermal annealing (RTA) is executed at a temperature of 750° C. for 30 seconds to convert the previously formed CoSi layers 121e, 121f, and 123a to CoSi₂ layers 21e, 21f, and 23a.

Similar to the previous embodiment, the step of RTA in FIG. 16C may also be replaced by a thermal treatment performed at a temperature from 650° C. to 750° C. for 10 to 120 seconds, or by a spike annealing at a temperature from 800° C. to 1000° C.

According to the present embodiment, because the titanium nitride protection film 25 is formed to have a thickness less than 20 nm, the titanium nitride protection film 25 has a nano-grain structure, and this blocks the diffusion path of oxygen atoms to the titanium nitride protection film 25. This eliminates the problem in formation of new oxide films on the silicon surfaces due to the residual oxygen atoms existing in the atmosphere used in thermal treatment, and the problem of non-uniformity in silicide formation.

In addition, in the present embodiment, because the titanium nitride protection film 25 is very thin, a small amount of oxygen atoms among the residual oxygen atoms existing in the atmosphere used in thermal treatment may diffuse through the titanium nitride film and enter into the cobalt film 24. These oxygen atoms in the cobalt film 24, together with the titanium atoms diffused from the titanium nitride protection film 25, have functions of pinning the movement of cobalt atoms in the cobalt film 24, especially in regions where the cobalt film 24 covers the side wall insulating films 23A, 23B of the poly-silicon gate electrode 23. This effectively prevents the supply of cobalt atoms from a portion of the cobalt film 24 covering the sidewall insulating films 23A and 23B of the poly-silicon gate electrode 23 to the poly-silicon gate electrode 23 where silicide is to be formed. As a result, the problem of high resistance CoSi being formed because of excess cobalt atoms and shortage of silicon atoms in the thermal treatment in FIG. 16C, and the sheet resistances of the CoSi₂ layers 21e, 21f, and 232a fluctuating is attenuated.

While the invention is described above with reference to specific embodiments chosen for purpose of illustration, it should be apparent that the invention is not limited to these embodiments, but numerous modifications could be made thereto by those skilled in the art without departing from the basic concept and scope of the invention.

What is claimed is:

1. A method of producing a semiconductor device having a gate width less than 50 nm, comprising:
a step of forming a poly-silicon gate electrode pattern having a gate width less than 50 nm on a semiconductor substrate;
a step of forming a first diffusion region and a second diffusion region on two respective sides of the poly-silicon gate electrode pattern in the semiconductor substrate;
a step of depositing a cobalt film on the semiconductor substrate so as to cover the first diffusion region, the second diffusion region, and the poly-silicon gate electrode pattern;
a step of depositing a titanium nitride film on the cobalt film; and
a step of, after the step of depositing the titanium nitride film, inducing a reaction between the cobalt film and surfaces of the first diffusion region, the second diffusion region, and the poly-silicon gate electrode pattern so as to form a CoSi₂ film;
wherein the titanium nitride film is formed such that a crystal grain diameter of the titanium nitride film is less than a thickness of the titanium nitride film.

2. The method as claimed in claim 1, wherein the grain diameter is less than or equal to 10 nm.

3. A method of producing a semiconductor device having a gate width less than 50 nm, comprising:
a step of forming a poly-silicon gate electrode pattern having a gate width less than 50 nm on a semiconductor substrate;
a step of forming a first diffusion region and a second diffusion region on two respective sides of the poly-silicon gate electrode pattern in the semiconductor substrate;
a step of depositing a cobalt film on the semiconductor substrate so as to cover the first diffusion region, the second diffusion region, and the poly-silicon gate electrode pattern;
a step of depositing a titanium nitride film on the cobalt film; and
a step of, after the step of depositing the titanium nitride film, inducing a reaction between the cobalt film and surfaces of the first diffusion region, the second diffusion region, and the poly-silicon gate electrode pattern so as to form a CoSi₂ film;
wherein the titanium nitride film is formed to have an amorphous phase.

4. A method of producing a semiconductor device having a gate width less than 50 nm, comprising:
a step of forming a poly-silicon gate electrode pattern having a gate width less than 50 nm on a semiconductor substrate;
a step of forming a first diffusion region and a second diffusion region on two respective sides of the poly-silicon gate electrode pattern in the semiconductor substrate;
a step of depositing a cobalt film on the semiconductor substrate so as to cover the first diffusion region, the second diffusion region, and the poly-silicon gate electrode pattern;
a step of depositing a titanium nitride film on the cobalt film, a composition of said titanium nitride film being denoted as TiₓN_{y} (x+y=1); and
a step of, after the step of depositing the titanium nitride film, inducing a reaction between the cobalt film and surfaces of the first diffusion region, the second diffusion region, and the poly-silicon gate electrode pattern so as to form a CoSi₂ film;
wherein the composition of the titanium nitride film satisfies x>y.

5. The method as claimed in claim 4, wherein the composition of the titanium nitride film satisfies 1.0<x/y<5.0.

6. The method as claimed in claim 4, wherein composition parameters x and y of the titanium nitride film are set so that an atomic percentage of titanium in the CoSi₂ film is not less than 0.1%, and not greater than 1%.

7. The method as claimed in claim 1, wherein the thickness of the titanium nitride film is less than or equal to 20 nm.

8. The method as claimed in claim 3, wherein a thickness of the titanium nitride film is less than or equal to 20 nm.

9. The method as claimed in claim 4, wherein a thickness of the titanium nitride film is less than or equal to 20 nm.

10. The method as claimed in claim 1, wherein the titanium nitride film is in contact with the cobalt film.

11. The method as claimed in claim 3, wherein the titanium nitride film is in contact with the cobalt film.

12. The method as claimed in claim 4, wherein the titanium nitride film is in contact with the cobalt film.

13. The method as claimed in claim 1, wherein the step of forming the CoSi₂ film comprises:
a step of inducing a reaction between the cobalt film and the surfaces of the first diffusion region, the second diffusion region, and the poly-silicon gate electrode pattern at a first temperature, so as to form a CoSi film;
a step of removing residues of the cobalt film and the titanium nitride film; and
a step of inducing a reaction between the CoSi film and the surfaces of the first diffusion region, the second diffusion region, and the poly-silicon gate electrode pattern at a second temperature higher than the first temperature, so as to convert the CoSi film to the CoSi₂ film.

14. The method as claimed in claim 3, wherein the step of forming the CoSi₂ film comprises:
a step of inducing a reaction between the cobalt film and the surfaces of the first diffusion region, the second diffusion region, and the poly-silicon gate electrode pattern at a first temperature, so as to form a CoSi film;
a step of removing residues of the cobalt film and the titanium nitride film; and
a step of inducing a reaction between the CoSi film and the surfaces of the first diffusion region, the second diffusion region, and the poly-silicon gate electrode pattern at a second temperature higher than the first temperature, so as to convert the CoSi film to the CoSi₂ film.

15. The method as claimed in claim 4, wherein the step of forming the CoSi₂ film comprises:
a step of inducing a reaction between the cobalt film and the surfaces of the first diffusion region, the second diffusion region, and the poly-silicon gate electrode pattern at a first temperature, so as to form a CoSi film;
a step of removing residues of the cobalt film and the titanium nitride film; and
a step of inducing a reaction between the CoSi film and the surfaces of the first diffusion region, the second diffusion region, and the poly-silicon gate electrode pattern at a second temperature higher than the first temperature, so as to convert the CoSi film to the CoSi₂ film.

16. A semiconductor device, comprising:
a semiconductor substrate;
a poly-silicon gate electrode pattern having a gate width less than 50 nm formed on the semiconductor substrate with a gate insulating film in between; and
a first diffusion region and a second diffusion region in the semiconductor substrate on two respective sides of the poly-silicon gate electrode pattern and on respective outer sides of sidewall insulating films of the poly-silicon gate electrode;
wherein
a CoSi₂ film is formed on surfaces of the first-diffusion region, the second diffusion region, and the poly-silicon gate electrode pattern, and
an atomic percentage of titanium in the CoSi₂ film is in a range from 0.1% to 1%.
